(19) United States
(12) Patent Application Publication
(10) Pub. No.: US 2008/0185181 A1
(43) Pub. Date: Aug. 7, 2008

(54) Alternating via fanout patterns

(76) Inventor: Charles L. Pfeil, Boulder, CO (US)

Correspondence Address: MENTOR GRAPHICS CORP.;PATENT GROUP, 8005 SW BOECKMAN ROAD, WILSONVILLE, OR, 97070-7777, US

(21) Appl. No.: 11/983,797

(22) Filed: Nov. 8, 2007

Related U.S. Application Data
(60) Provisional application No. 60/864,972, filed on Nov. 8, 2006.

(51) Int. Cl. H01R 12/06; H05K 3/40

(52) U.S. Cl. 174/267; 29/842

(57) ABSTRACT

Various techniques are disclosed for identifying different fanout via configurations that can be created using fanout vias, and then arranging those fanout via configurations in an alternating manner in order to increase the amount and/or area of routing channels available to route traces to the fanout vias. According to some of these techniques, a first fanout via configuration is selected, which can connect a component pin to a first layer of a multilayer printed circuit board. Next, a second fanout via configuration is selected, which can connect a component pin to a second layer of a multilayer printed circuit board different from the first layer. When the printed circuit board is designed, lines of these vias configurations are formed to correspond to a component that will be mounted on the printed circuit board. Each line will have a series of the first fanout via configuration alternating with a series of the second fanout via configuration. Further, two or more fanout via configurations of the same type can be arranged into a via configuration model. A printed circuit board design may then have lines of different via configuration models, such that each line has a series of one type of fanout via configuration model alternating with a series of another type of via fanout configuration model. Alternately or additionally, yet another type of fanout via configuration may be identified. Fanout via configurations of this other type may then be placed along a diagonal line bisecting the area of a printed circuit board design corresponding to the location at which a component will be mounted, in order to preserve routing channel area along the diagonal line.

### RELATED APPLICATIONS

This application claims priority to U.S. Provisional Patent Application No. 60/864,972, entitled “Alternating Via Fanout Patterns,” filed on Nov. 8, 2006, and naming Charles Pfeil as inventor, which application is incorporated entirely herein by reference.

### FIELD OF THE INVENTION

The present invention is directed to improving the routability of traces during the design of a printed circuit board. Aspects of the invention have particular applicability to the placement of alternating via structures in printed circuit board so as to provide extra routing channels for routing traces on the circuit board.

### BACKGROUND OF THE INVENTION

Integrated circuit devices are used in a wide variety of modern appliances, such as computers, automobiles, telephones, televisions, manufacturing tools, satellites and even toys. While even a small integrated circuit device can provide a great deal of functionality, almost every integrated circuit device must be electrically connected to an input or output device, to another integrated circuit device, or to some other electronic component in order to be useful. To provide these electrical connections, integrated circuit devices are typically mounted on a printed circuit board (PCB). Most printed circuit boards have a rigid, planar core. The core may be formed, for example, of a sheet of fiberglass material impregnated with epoxy. Conductive lines or “traces” then are formed on one or both surfaces of the core, to electronically connect the components attached to the printed circuit board. The traces may be formed of any desired conductive material, such as copper. With various manufacturing techniques, material, specific traces may be created by etching a single layer of conductive material in a photolithographic process.

Simple printed circuit boards may have only a single core, with traces on one or both sides of the core. More complex printed circuit boards, however, may have multiple cores, with traces on one or both sides of one or more of the cores. These multilayered printed circuit board also may include layers of insulating material, to prevent traces on adjacent core surfaces from contacting. In addition, a multilayered printed circuit board also will include one or more “vias” to electrically connect two or more different layers of the board. A via is created by drilling or otherwise forming a hole through one or more cores. The walls of the via then may be clad with conductive material to form an electrical connection between the different layers. Alternately or additionally, the entire via may be filled with conductive material to form the electrical connection. Some vias will pass through every layer of the board, while other vias may connect only some of the layers in the board.

There are a number of steps performed in the design of a printed circuit board. Initially, a designer will create a schematic diagram for the system to be connected through the printed circuit board. This process includes identifying each component that will be included in the system. A system can include “active” components, such as field programmable gate array (FPGA) integrated circuits or application-specific integrated circuits (ASICs). A system also can include “passive” components, such as connectors formed as an integrated circuit, resistors, capacitors, and inductors. In addition to identifying each component, the schematic design will represent the electrical connections that must be formed between each component. Next, a designer typically will verify the functionality of the system described in the schematic design. The design may, for example, use software modeling tools to ensure that the system described in the schematic will reliably perform the desired operations. If any errors are detected, then the schematic design will be corrected to address the errors, and the functional verification process repeated.

Once the schematic design is finalized, then the designer will create a physical design to implement the schematic design. The designer will begin by selecting a physical location in the design for each component. When a location for a component has been selected, the designer will add a component object, representing that component, to that location in the printed circuit board design. The component object may include a variety of information regarding the physical component it represents, such as the configuration of the connection pins used to electrically connect that component to other components. With an integrated circuit device, for example, the substrate with the integrated circuit will be encased in a package for protection from the environment. The pins serve to provide an electrical connection, through the packaging, to the electrical contacts of the integrated circuit. After the component objects for the components are located in the printed circuit board design, the designer then will attempt to route traces in the printed circuit board design to connect the components as specified in the schematic design.

Various aspects of the system, however, may create a variety of constraints restricting how the designer can route the traces. For example, a component's minimum current requirement may require that the trace supplying that current have a minimum width. Also, traces may require a minimum separation distance to prevent unacceptable crosstalk. Still further, if a component requires a differential pair connection, then the traces used to implement that differential pair may need to have the same length and maintain a constant distance from each other. Timing constraints may limit the length and/or impedance of a trace. Moreover, because a trace cannot cross over another trace, connections between component pins may require routing traces on multiple layers of the printed circuit board.

Accordingly, after creating an initial physical design, a designer may revise it several times before it is finished. These revisions may include, for example, moving the pathways for traces, altering the width of traces at various points along their lengths creating partial traces or “hangers,” moving the location of one or more of the components, and rotating the orientation of one or more of the components. Each revision, however, may itself require related revisions. For example, if a component is moved or rotated, then every existing trace associated with that component must be discarded and replaced.

After the designer has established a physical design for the printed circuit board, it is analyzed to verify that it meets specified parameters. For example, the design may be analyzed to confirm that it complies with various manufacturing constraints, such as minimum spacing between traces, minimum trace widths, minimum or maximum turn angles for traces, etc. Alternately or additionally, the designer may verify that the signal integrity and timing delays for the physical design meet desired parameters, to ensure that the signals to be carried by the traces will not be degraded by crosstalk, overshoot or undershoot. Still further, the designer may verify that the electromagnetic radiation that will be generated by the physical design will not exceed specified parameters. These verification processes may be performed using, for example, conventional printed circuit board design verification software tools. If any errors are detected, then the physical design will be corrected to address the errors, and the verification processes repeated. Thus, complying with the verification requirements may necessitate several more changes to the physical design.

As integrated circuit devices have evolved to include smaller and more circuits, it has become increasing difficult to create a physical design for a printed circuit board. For example, a D-type positive edge triggered flip-flop circuit may require 14 pins. Whereas an integrated circuit device might have included only a single circuit of this type several years ago, improvements in integrated circuit manufacturing may now allow an even smaller integrated circuit device to include hundreds of these circuits, requiring more than a thousand pins in a reduced area.

New pin configurations have been developed to permit these more complex integrated circuit devices. Many integrated circuit devices, for example, now use a ball grid array (BGA) structure. With a ball grid array, the pins are formed by balls of solder mounted on the bottom of the package encasing the integrated circuit device. The printed circuit board in turn has a corresponding array of pads, formed of a conductive material such as copper, which matches the positions of the solder balls on the integrated circuit device. To connect the integrated circuit device to the printed circuit board, the integrated circuit device is placed on the printed circuit board so that the balls of solder align with the conductive pads. The solder balls then are melted onto the pads, typically in a reflow oven or by using an infrared heater.

While these new pin configuration allow an integrated circuit device to provide a large number of pins in a relatively small area, their compactness increases the difficulty in routing traces to the pins. As shown in FIG. 1, for example, a ball grid array 101 may have a square array of 1760 pins 103 with a spacing of only 1 mm between adjacent pins. With this arrangement, there are only 160 “spaces” between adjacent pins around the perimeter of the array through which to route traces to the pins on a printed circuit board. There are 1600 pins within the perimeter of the array, however. Even if the routing constraints allow two traces to be routed between adjacent pins, traces can be directly routed to only 320 of the pins within the perimeter of the array. While vias to multiple layers can be employed to route traces to more of the remaining 1280 pins, the addition of extra layers significantly increases the cost of manufacturing a printed circuit board. Moreover, even if additional layers are used, the routing for this type pin density will still be very complex. For example, FIG. 2 illustrates one possible routing of traces 201 for the ball grid array 101. Clearly, there are a number of pins 103 within the central area of the ball grid array 101 to which traces simply cannot be routed on the illustrated layer.

FIG. 3 more generally illustrates the pins of a conventional ball grid array to which it is easier and more difficult to route traces on a printed circuit board. As seen in this figure, the ball grid array 301 can be quartered by two imaginary diagonal lines, where each diagonal line extends from a different corner of the array to the opposite corner of the array. The more “difficult” routing areas 303 occur near the intersections of these diagonal lines, while the “easier” routing areas 305 occur at the corners of the ball grid array 301. As will be readily understood from the figure, traces can be routed to the pins in an area 305 from two sides of the ball grid array 301 without requiring that those traces pass by a large number of pins. In order to reach a pin in an area 303, however, any trace will have to pass through approximately a third of the total number of pins in the ball grid array 301 or more.

As previously noted, in order to route traces to more of the pins of a component, conventional circuit boards will route traces on multiple layers, and then employ one or more vias to connect the traces to the layer on which the pins of the component are mounted. FIG. 4 illustrates an example of the types of vias that may be employed in a multilayer printed circuit board 401. More particularly, FIG. 4 illustrates a printed circuit board 401 having twelve different layers 403-425. As seen in this figure, a solder pin 427 is mounted on a ball pad 429. In addition, a via 431 is formed in the printed circuit board 401, connecting a pad on the first layer 403 with a pad on the second layer 405. A second via 433 then is formed in the printed circuit board 401, connecting a pad on the first layer 403 with a pad on the third layer 407. Yet a third via 435 is formed in the printed circuit board 401, connecting a pad on the second layer 405 with a pad on the eleventh layer 423.

Each of these vias may be referred to as “blind” vias, because they do not extend to each layer of the board. (A via extending to or through each layer of a printed circuit board will often be referred to as a “through” via.) The vias 431 and 433 also may be referred to as “micro” vias. As known in the art, various techniques, such as laser drilling, allow some vias to be formed with much smaller sizes as compared to vias formed using conventional drilling techniques. The via 435 also may be referred to a “buried” via, because it does not extend to either the uppermost layer or the lowermost layer of the printed circuit board 401. When a via is used to route a trace to a pin on another layer, the via may be referred to as a “fanout” via.

### BRIEF SUMMARY OF THE INVENTION

Various aspects of the invention relate to techniques for identifying different fanout via configurations that can be created using fanout vias, and then arranging those fanout via configurations in an alternating manner in order to increase the amount and/or area of routing channels available to route traces to the fanout vias. According to various implementations of the invention, a first fanout via configuration is selected, which can connect a component pin to a first layer of a multilayer printed circuit board. Next, a second fanout via configuration is selected, which can connect a component pin to a second layer of a multilayer printed circuit board different from the first layer. When the printed circuit board is designed, lines of these vias configurations are formed to correspond to a component that will be mounted on the printed circuit board. Each line will have a series of the first fanout via configuration alternating with a series of the second fanout via configuration. With some implementations of the invention, two or more fanout via configurations of the same type can be arranged into a via configuration model. With these implementations, a printed circuit board design will have lines of different via configuration models, such that each line has a series of one type of fanout via configuration model alternating with a series of another type of via fanout configuration model.

Alternately or additionally, yet another type of fanout via configuration may be identified. Fanout via configurations of this third type may then be placed along a diagonal line bisecting the area of a printed circuit board design corresponding to the location at which a component will be mounted. These and other features and aspects of the invention will be apparent upon consideration of the following detailed description.

### BRIEF DESCRIPTION OF THE DRAWINGS

FIG. 1 illustrates an example of a ball grid array having a square array of 1760 pins.

FIG. 2 illustrates an example of traces that may be routed for the ball grid array illustrated in FIG. 1.

FIG. 3 generally illustrates the pins of a conventional ball grid array to which it is easier and more difficult to route traces on a printed circuit board.

FIG. 4 illustrates an example of the types of vias that may be employed according to various examples of the invention.

FIG. 5 illustrates one example of a fanout via configuration and an associated fanout via configuration model that may be employed according to various implementations of the invention.

FIG. 6 illustrates another example of a fanout via configuration and an associated fanout via configuration model that may be employed according to various implementations of the invention.

FIG. 7 illustrates a first layer of a printed circuit board design employing the fanout via configurations illustrated in FIGS. 5 and 6.

FIG. 8 illustrates a second layer of a printed circuit board design employing the fanout via configurations illustrated in FIGS. 5 and 6.

FIG. 9 illustrates a third layer of a printed circuit board design employing the fanout via configurations illustrated in FIGS. 5 and 6.

FIG. 10 illustrates yet another fanout via configuration that may be implemented in a printed circuit board design according to various examples of the invention.

FIGS. 11 and FIG. 12 illustrate a first layer of a printed circuit board design employing the fanout via configuration illustrated in FIGS. 10.

FIG. 13 illustrate another layer of a printed circuit board design employing the fanout via configuration illustrated in FIGS. 10.

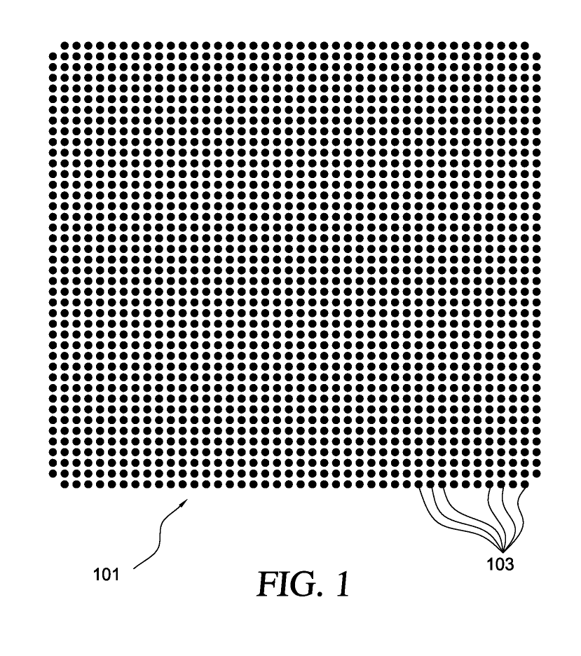

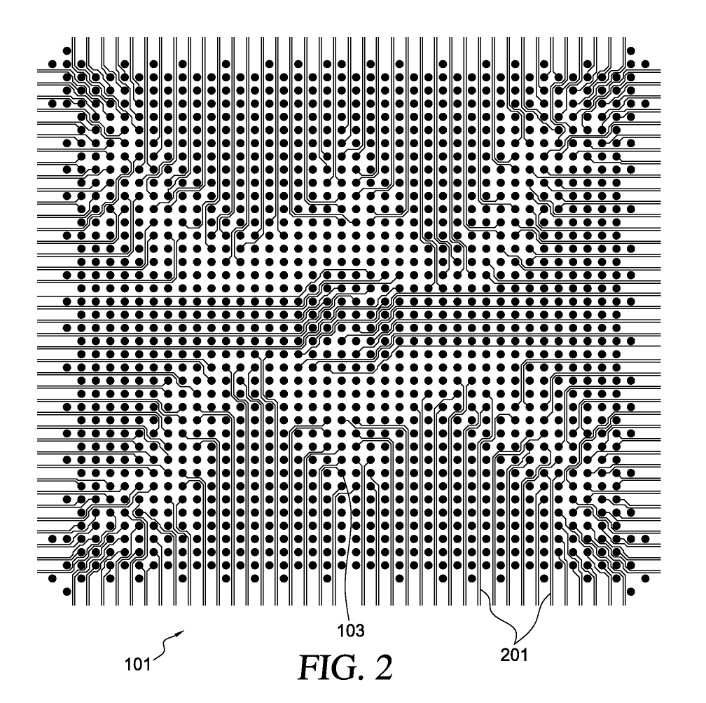

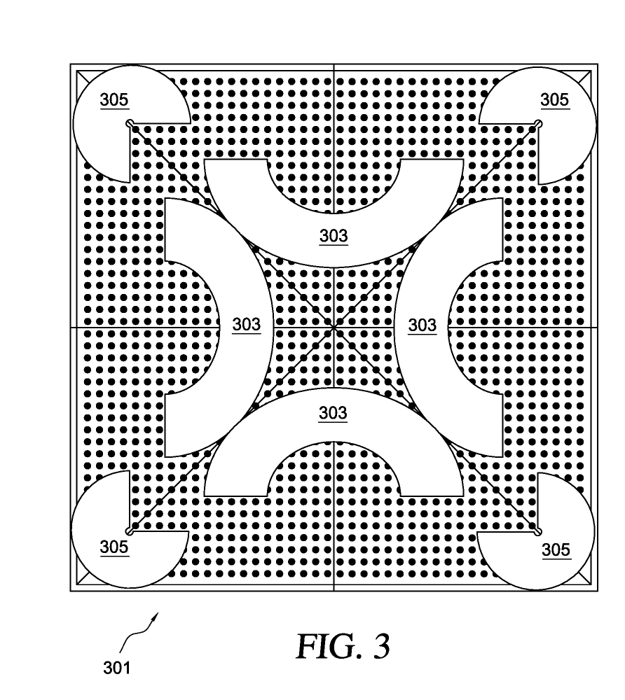

### DETAILED DESCRIPTION OF THE INVENTION

### Fanout Via Configurations

As will be discussed in more detail below, various implementations of the invention are related to the arrangement of fanout via configurations in a printed circuit board design. As used herein, the terms “design” and “design data” are intended to encompass data describing an entire printed circuit board. These terms also are intended to encompass a smaller set of data describing a subset of an entire printed circuit board, however, such as a layer of an printed circuit board, or even a portion of a layer of an printed circuit board. Still further, the terms “design” and “design data” are intended to encompass data describing more than one printed circuit board, such as data to be used to create a system of interconnected printed circuit boards.

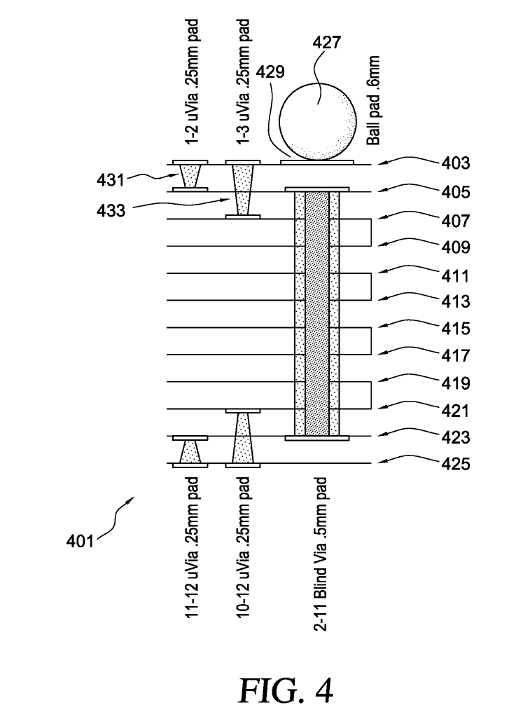

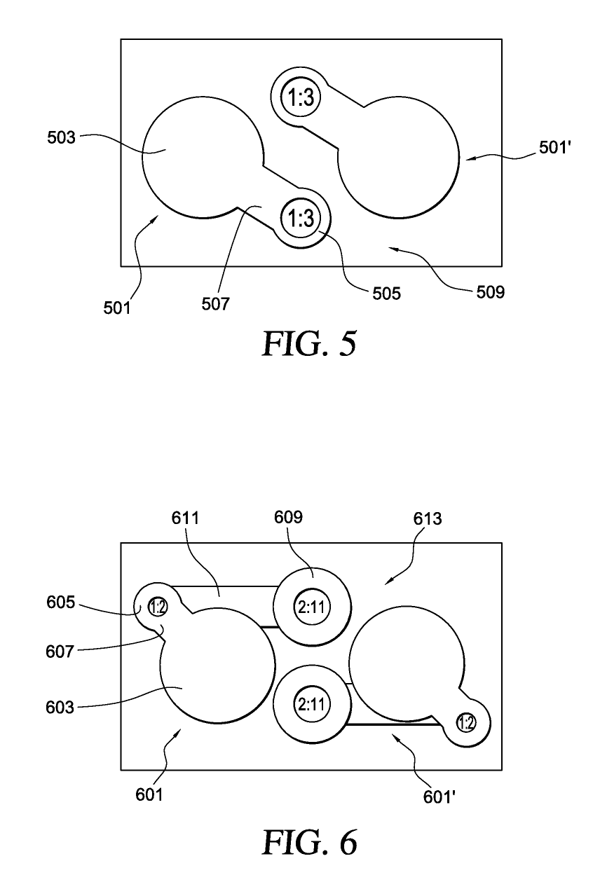

Turning now to FIG. 5, this figure illustrates a fanout via configuration 501 that can be implemented on a twelve-layer printed circuit board (such as the printed circuit board 401 shown in FIG. 4). As seen in this figure, the fanout via configuration 501 includes a pad 503, a via 505, and a trace 507 connecting the pad 503 to the via 505. With the fanout via configuration 501, the via 505 connects the first layer of the printed circuit board with the third layer of the printed circuit board, like the via 433 shown in FIG. 4. As also illustrated in FIG. 5, a second instance of the fanout via configuration 501′ can be placed adjacent to the first instance of the fanout via configuration 601 to form a fanout via configuration model 509. With the illustrated fanout via configuration model 509, the vias 505 are placed along a line approximately halfway between the pads 503 of each fanout via configuration 501. As will be discussed in more detail below, this arrangement helps to maximize the route channel area available on the third layer of the printed circuit board.

FIG. 5 illustrates yet another fanout via configuration 601 that also can be implemented on a twelve-layer printed circuit board. As seen in this figure, the fanout via configuration 601 includes a pad 603, a via 605, and a trace 607 connecting the pad 603 to the via 605. With the fanout via configuration 601, the via 605 connects the first layer of the printed circuit board with the second layer of the printed circuit board, like the via 431 shown in FIG. 4. In addition, the fanout via configuration 601 includes a second via 609 and a second trace 611. The second via 609 extends from the second layer of the printed circuit board to the eleventh layer of the printed circuit board. Accordingly, the second trace 611 runs along the second layer of the printed circuit board, connecting the portion of the first via 605 existing on the second layer with the portion of the second via 609 existing on the second layer.

As also illustrated in FIG. 6, another instance of the fanout via configuration 601′ can be placed adjacent to the first instance of the fanout via configuration 601 to form a fanout via configuration model 513. With the illustrated fanout via configuration model 513, the secondary vias 609 are placed along a line approximately halfway between the pads 603 of each fanout via configuration 601. As will be discussed in more detail below, this arrangement helps to maximize the route channel area available on the second layer of the printed circuit board.

### Printed Circuit Board Designs And Printed Circuit Boards

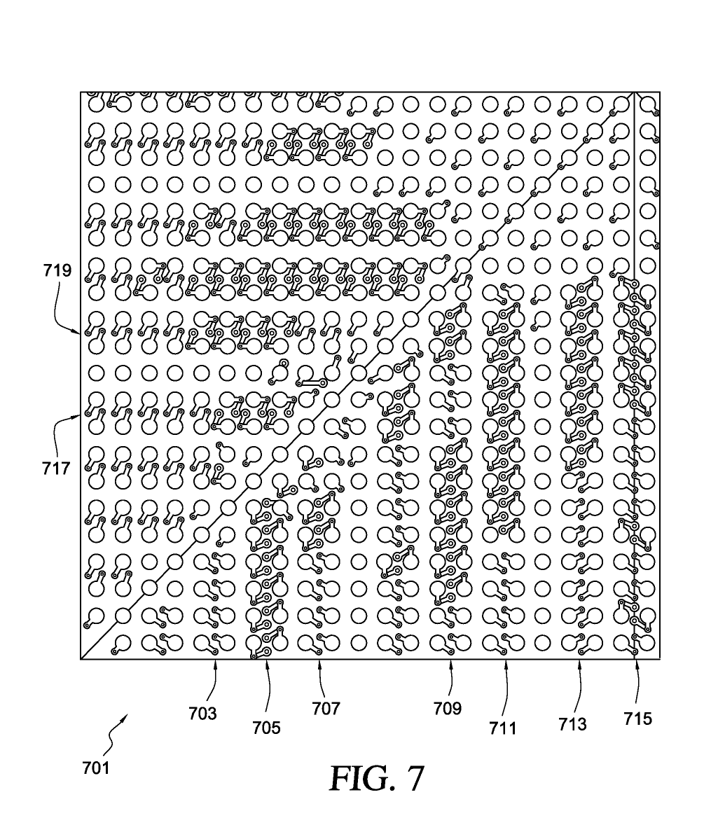

FIG. 7 illustrates the use of the fanout via configuration models 501 and 601 in a printed circuit board design 701. As seen in this figure, the printed circuit board design 701 includes several lines of fanout via configurations. Some lines, such as the line 703, for example consist almost entirely of the fanout via configurations 501 (arranged as a series of the fanout via configuration models 509). Other lines, such as the line 705, consist almost entirely of the fanout via configurations 601 (arranged as a series of the fanout via configuration models 613). Still other lines, however, such as lines 707-719, have a series of the fanout via configurations 501 alternating with a series of the fanout via configuration 601. More particularly, lines 707-719 have a series of the fanout via configuration models 501 alternating with a series of the fanout via configuration models 613.

For example, line 709 has a series of two of the fanout via configuration models 501 starting from the edge of the printed circuit board design 701. This series of the fanout via configuration models 501 is then followed by six of the fanout via configuration models 613, followed by another series of three of the fanout via configuration models 501. This series of three of the fanout via configuration models itself is then followed by a series of two of the fanout via configuration models 613. Similarly, line 711 has a series of four fanout via configuration models 501 starting from the edge of the printed circuit board design 701. This series of the fanout via configuration models 501 is then followed by a series of eight of the fanout via configuration models 613 (with an intermediate unconnected pad and a single instance of the fanout via configuration 601). Thus, these lines have a series of vias extending to one layer of the printed circuit board design (i.e., the first layer), alternating with another series of vias extending to a different layer of the printed circuit board design (i.e., the third layer).

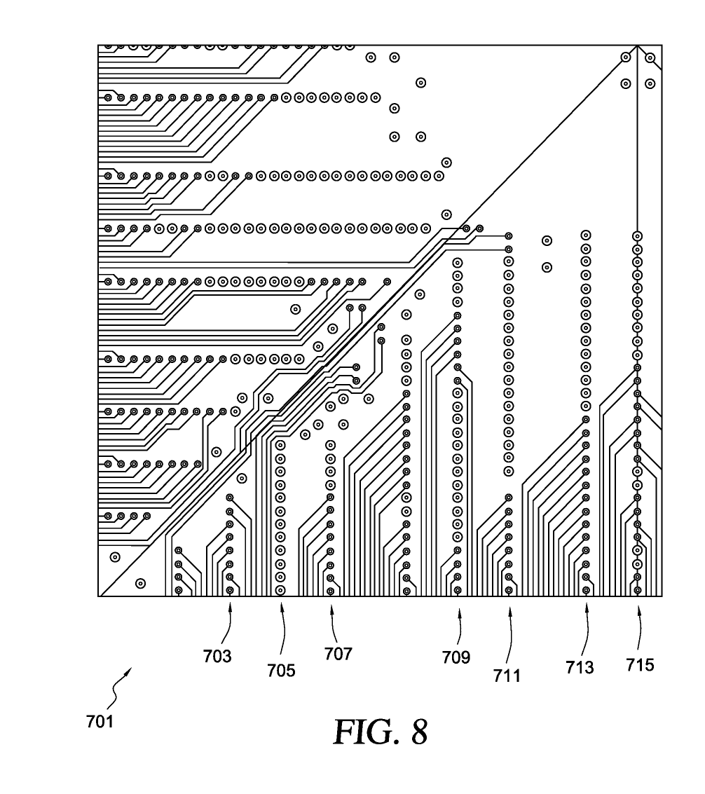

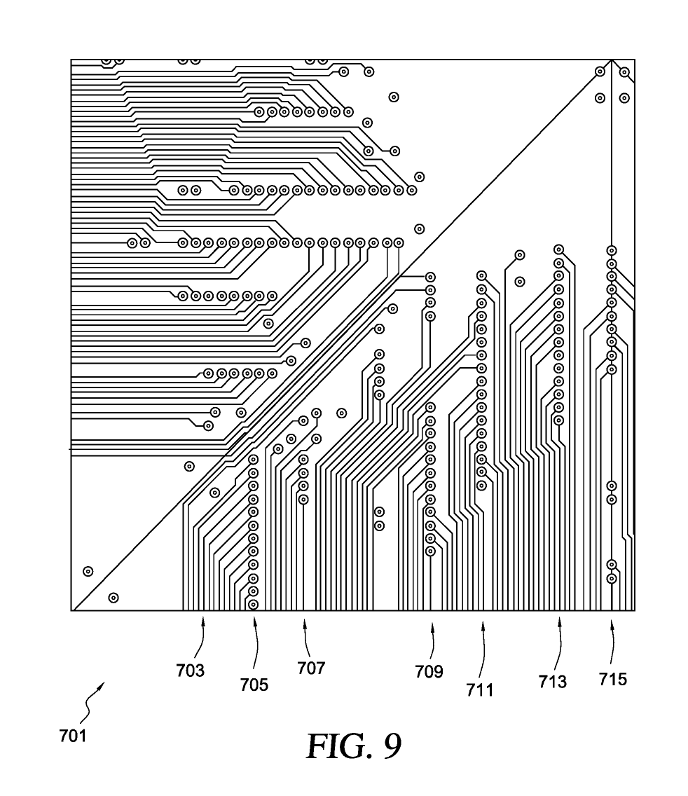

The effect of this alternative fanout via arrangement can be seen in FIGS. 8 and 9. As previously noted, with the fanout via configuration model 613, the vias 609 are arranged along a line approximately halfway between the pads 603 of the fanout via configuration 601. As seen in FIG. 8, which illustrates the second layer of the printed circuit board 701, this arrangement provides a large amount of routing channel area between the vias 609 in adjacent rows, such the row 711 and the row 713. Moreover, because many of the other fanout via configurations in these rows are the fanout via configuration 501 with vias 505 extending to the third layer, these fanout via configurations 501 do not require traces in the second layer. This allows sufficient routing channel area to route traces to the vias 605 of the fanout via configurations 601.

Similarly, with the fanout via configuration model 501, the vias 505 are arranged along a line approximately halfway between the pads 503 of the fanout via configurations 501. As seen in FIG. 9, which illustrates the third layer of the printed circuit board 701, this arrangement provides a large amount of routing channel area between the vias 505 in adjacent rows, such the row 711 and the row 713. Again, because many of the other fanout via configurations in these rows are the fanout via configuration 601 with vias 609 extending through the third layer, these fanout via configurations 501 do not require traces in the third layer. This allows sufficient routing channel area to route traces to the vias 505 of the fanout via configurations 501.

It should be appreciated that, while two particular fanout via configurations have been described in detail (with two corresponding fanout via configuration models), a variety of different fanout via configurations can be employed according to various examples of the invention. That is, other implementations of the invention may employ different types of fanout via configurations, where the fanout via configurations have vias extending to different layers. If these other fanout via configurations (or fanout via configuration models arranged from these other fanout via configurations) are arranged in alternating series, they can provide the benefits of the invention described in detail above with respect to the fanout via configurations 501 and 601. Accordingly, the specific application of the fanout via configurations 501 and 601 are intended to be only examples of fanout via configurations that may be employed according to various embodiments of the invention, and are not intended to be limiting.

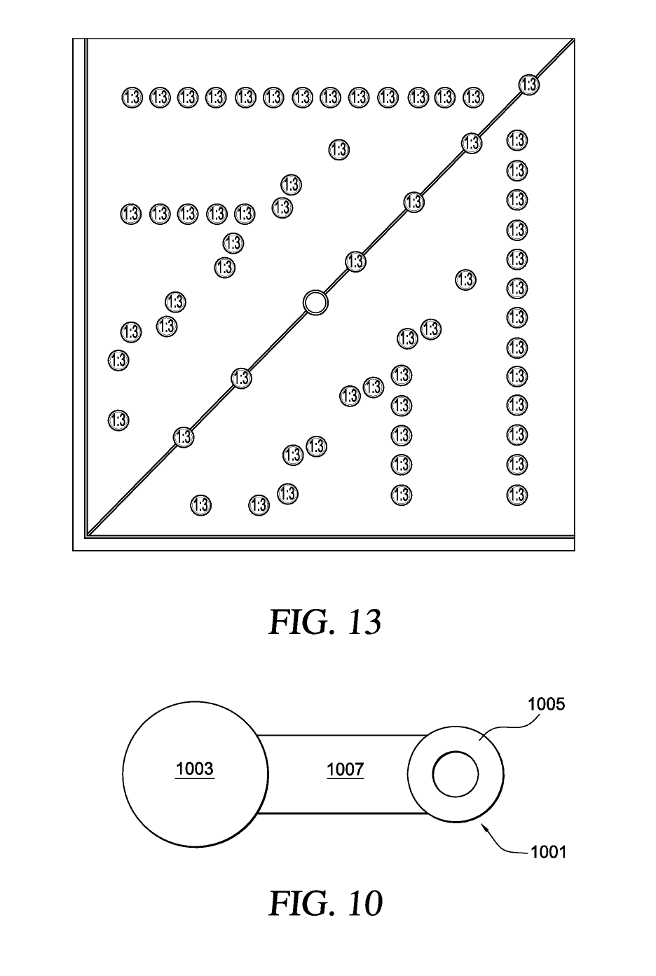

FIG. 10 illustrates another example of a fanout via configuration that can be employed according to various implementations of the invention. As seen in this figure, the fanout via configuration 1001 has a pad 1003, a via 1005, and a trace 1007 connecting the pad 1003 to the via 1005. The via 1005 connects the first layer of the printed circuit board with the third layer of the printed circuit board, like the via 433 shown in FIG. 4.

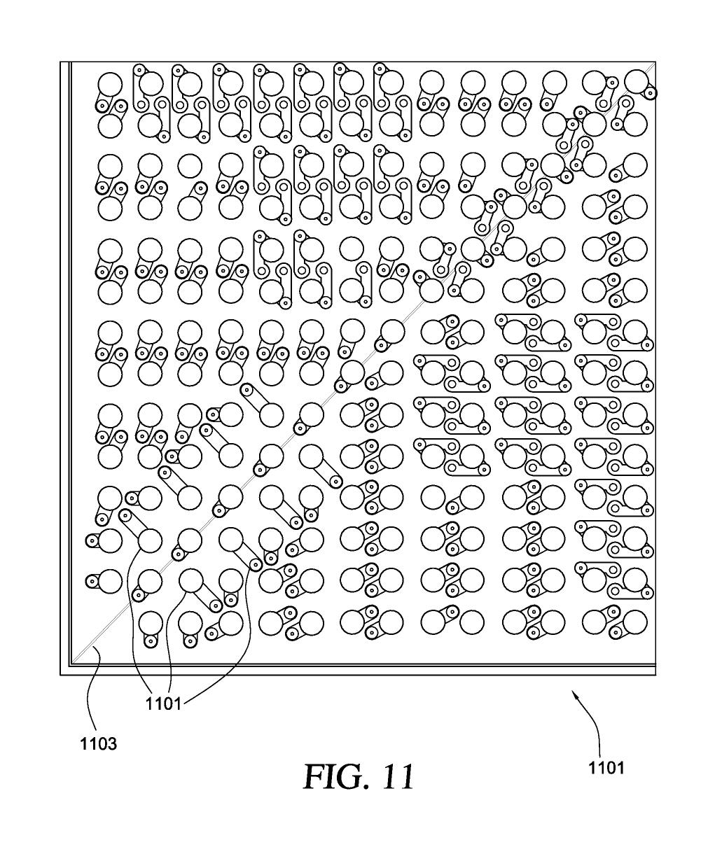

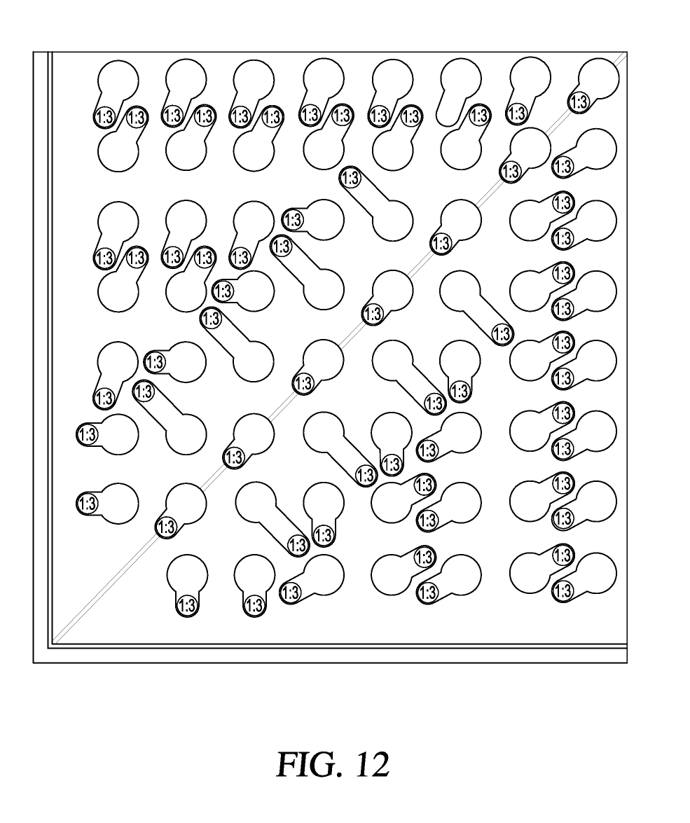

FIG. 11 and FIG. 12 (which is an enlargement of a portion of the area shown in FIG. 11) illustrate how the fanout via configuration 1001 can be used to increase the amount routing channel area along a diagonal line bisecting a pin array along opposite corners. As see in this figure, instances of the fanout via configuration 1001 are placed in a printed circuit board design 1101 along a diagonal line 1103 that extends between opposite corners of the pin array. As seen in these figure, the instances of the fanout via configuration 1001 are positioned to that their traces 1007 extend away from and are approximately orthogonal to the diagonal line 1103. Thus, the vias 1005 are placed as far away as possible from the line 1103. The impact of using the fanout via configuration 1001 in this manner can be seen in FIG. 13, which illustrates the corresponding area in the third layer of the printed circuit board design. As seen in this figure, placing the vias 1005 away from the diagonal line 1103 preserves additional routing channel area along either side of the diagonal line 1103. This arrangement in turns allows a greater number of traces to be routed from pins deep within the array along either side of the diagonal line 1103.

While no particular method of adding fanout via configurations (or instances of corresponding fanout via configuration models) has been discussed in detail above, it should be appreciated that any conventional printed circuit board design tool capabable of adding specific fanout via configurations to a printed circuit board design can be employed to implement various embodiments of the invention. Also, while various examples of the invention have been discussed with regard to printed circuit board designs, it will be appreciated that aspects of the invention may be embodied by manufacturing printed circuit boards incorporating alternating series of different fanout via configurations arranged in a line as discussed above, or by the manufactured boards themselves. Similarly it will be appreciated that aspects of the invention may be embodied by manufacturing printed circuit boards incorporating instances of a particular fanout via configuration arranged in a diagonal line as discussed above, or the manufactured boards themselves.

### Conclusion

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims.

1. A method of creating a printed circuit board, comprising:
selecting a first fanout via configuration which can connect a component pin to a first layer of a multilayer printed circuit board;
selecting a second fanout via configuration, which can connect a component pin to a second layer of a multilayer printed circuit board different from the first layer; and
adding a line of fanout via configurations to a printed circuit board design, such that the line of fanout via configurations includes a series of instances of the first fanout via configuration alternated with a series of instances of the second fanout via configuration.

2. The method recited in claim 1, wherein multiple instances of the first fanout via configuration are organized into at least one instance of a fanout via configuration model.

3. The method recited in claim 2, wherein multiple instances of the second fanout via configuration are organized into at least one instance of a second fanout via configuration model.

4. The method recited in claim 1, wherein multiple instances of the second fanout via configuration are organized into at least one instance of a fanout via configuration model.

5. The method recited in claim 1, further comprising:
selecting a third fanout via configuration; and
adding a plurality of instances of the third fanout via configuration along a diagonal line extending between opposite corners of a pin array in the printed circuit board design.

6. A printed circuit board manufactured according to the method recited in claim 1.

7. A method of creating a printed circuit board, comprising:
selecting a fanout via configuration having a trace and a via; and
adding a plurality of instances of the fanout via configuration along a diagonal line extending between opposite corners of a pin array in a printed circuit board design, such that the trace in each instance of the fanout via configuration extends away from the diagonal line.

8. The method recited in claim 7, wherein the trace in each instance of the fanout via configuration extends in a direction substantially orthogonal to the diagonal line.

9. A printed circuit board manufactured according to the method recited in claim 7.
